(19) United States
(12) Patent Application Publication
(10) Pub. No.: US 2012/0193226 A1
(43) Pub. Date: Aug. 2, 2012

(54) PHYSICAL VAPOR DEPOSITION SYSTEM

(76) Inventor: Russell A. Beers, Manchester, CT (US)

(21) Appl. No.: 13/019,323

(22) Filed: Feb. 2, 2011

(51) Int. Cl. C23C 14/35

(52) U.S. Cl. 204/298.16

(57) ABSTRACT

A steered arc physical vapor deposition (PVD) system includes an anode and a cathode. The cathode is a hollow cylindrical post cathode. A magnet is movably suspended within the cathode.

### BACKGROUND

The present disclosure relates to a steered arc physical vapor deposition system, and more particularly to a cylindrical post cathode for a steered arc physical vapor deposition system.

Physical vapor deposition (PVD) systems are utilized in cathodic arc coating to vaporize a material and deposit that material on a piece, thereby coating the piece with a thin layer of the material. PVD systems use a cathode/anode arrangement where the cathode includes an evaporation surface made from the coating material. The cathode and the anode of the PVD system are contained within a vacuum chamber. A power source is connected to the cathode and the anode with the positive connection of the power source connected to the anode and the negative connection of the power source connected to the cathode. By connecting the positive power connection to the anode and the negative power connection to the cathode, a charge disparity between the anode and the cathode is generated.

The charge disparity causes an electrical arc to jump between the cathode and the anode. In standard PVD systems, the arc location is random over the surface of the cathode. The arcing causes the evaporation surface of the cathode to vaporize at the point where the arc occurred. The vaporized cathode material then coats the piece contained in the vacuum chamber.

In order to control the density and distribution of the coating, steered arc systems control the location of the arc on the cathode's surface by manipulating magnetic fields.

### SUMMARY

Disclosed is a steered arc PVD assembly having a vacuum chamber, a post cathode inside the vacuum chamber, a magnet suspended within the post cathode, and a power source capable of providing a first charge to the post cathode and a second charge to an anode. The first charge and the second charge are opposite charges.

Also disclosed is a post cathode having a tube, and a ring magnet disposed within the tube. The ring magnet has an axis aligned with an axis of the tube. A side wall of the tube is an evaporation source material.

### BRIEF DESCRIPTION OF THE DRAWINGS

The disclosure can be further understood by reference to the following detailed description when considered in connection with the accompanying drawings wherein:

FIG. 1 schematically illustrates an example steered arc physical vapor deposition (PVD) system including a cylindrical post cathode.

FIG. 2 schematically illustrates an example steered arc PVD system incorporating actuation for magnet control.

FIG. 3 schematically illustrates an example steered arc PVD system incorporating fluid actuation for magnet control.

### DETAILED DESCRIPTION

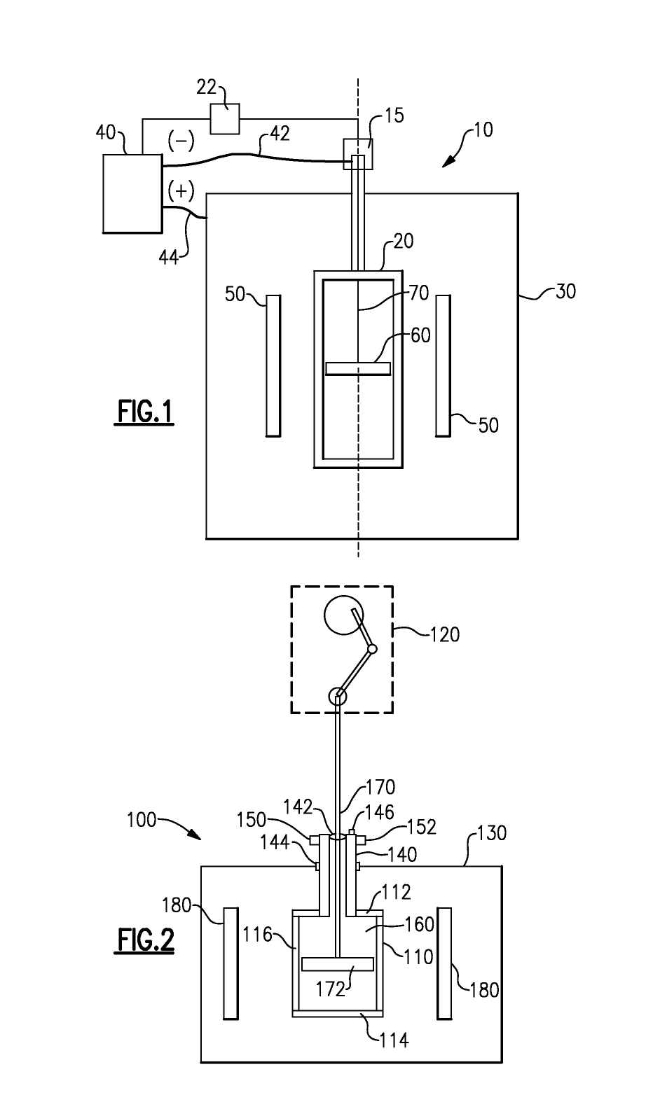

FIG. 1 illustrates an example steered arc physical vaporization deposition (PVD) system 10 that includes a cylindrical post cathode 20. The cylindrical post cathode 20 is a hollow cylindrical tube with a magnet 60 suspended within the tube via a shaft 70. A vacuum chamber 30 surrounds the post cathode 20, with the inner surfaces of the vacuum chamber 30 functioning as the anode. Alternately, a separate anode structure can be located within the vacuum chamber 30. A power source 40 provides a negative charge 42 to the cathode 20 and a positive charge 44 to the anode 30 during operation of the PVD system 10. A controller 22 directs operation of an actuation device 15 and application of electric power to the cathode 20 and the anode.

When the PVD system 10 is operating, the magnetic field generated by the magnet 60 forces the arc to occur at an intersection of the magnetic field and the surface of the cathode 20, thereby influencing where a vaporized coating will settle on a part 50. The magnet 60 is suspended within the post cathode 20 on the shaft 70. The shaft 70 moves the magnet 60 along an axis defined by the shaft 70, the magnet 60, and the post cathode 20. Shifting the position of the magnet 60, provides for positioning of the arc for controlling vapor deposition. The shaft 70 extends out of the vacuum chamber 30 and is connected to an actuation device 15. While the magnet 60 is described herein as a single magnet 60, it is understood that a magnet assembly, or some combination of permanent magnets and electromagnets, could also be used with minimal modification to the disclosure.

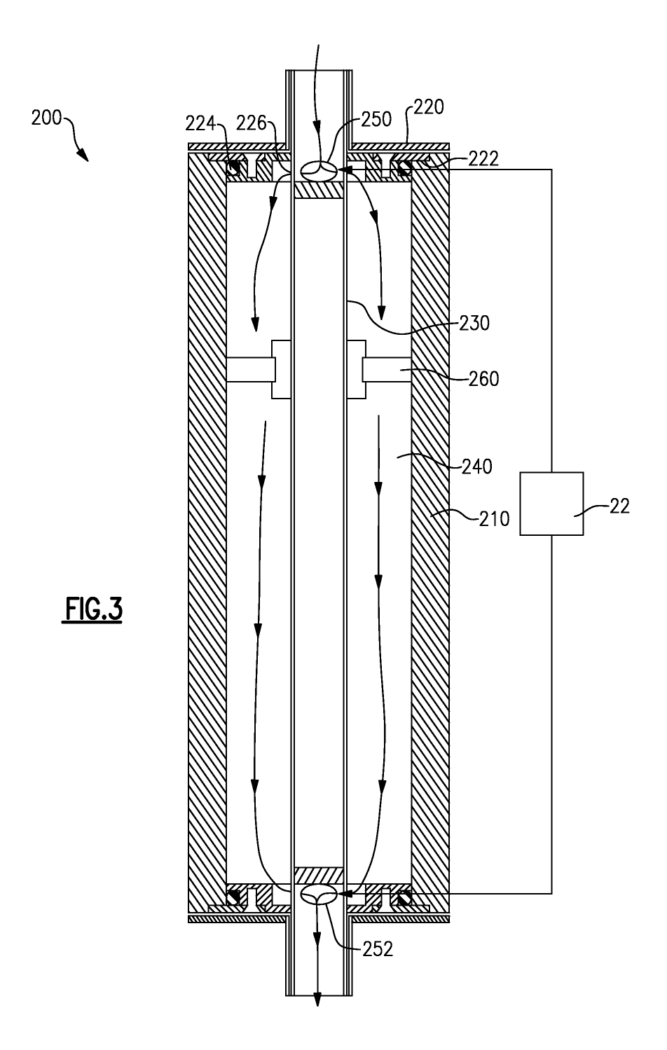

FIG. 2 illustrates an example PVD system 100 including a magnet shaft 170 actuated by a cam system 120, for controlling magnet 172 position. A cylindrical post cathode 110 is suspended in the vacuum chamber 130 via a shaft 140. The shaft 140 includes a center passageway 142 through which the magnet shaft 170 passes. The magnet shaft 170 is attached to magnet 172, and maintains the magnet 172 in a desired position or moves the magnet 172 to a new position. The shaft 140 includes a seal 144 where it enters the vacuum chamber 130 for maintaining the vacuum. An electrical charge can be provided to the cathode 110 through an electrical connector 146 on the cooling shaft 140. The cooling shaft 140 further includes fluid passageways 150, 152, which provide for the inlet and outlet of a cooling fluid 160. The cooling fluid 160 cools the post cathode 110, and can be any known cooling fluid.

The cylindrical post cathode 110 has a top cap portion 112, a bottom cap portion 114 and a side wall portion 116. The side wall portion 116 is an evaporation source material that is evaporated during a cathodic arc. The vapor is deposited on an adjacent part 180 to provide a thin coating of the source material on the workpiece.

Alternate PVD systems using cylindrical post cathodes 110 may not require a cooling fluid. These PVD systems do not include the cooling fluid inlet and outlet 150, 152, with all other features being substantially the same as the above described example. Another example PVD system replaces the camshaft actuation system 120 with a linear actuator, to provide desired precision and accuracy over movement and positioning of the magnet 172.

A fluid actuating system can be implemented as an alternate to the above described mechanical actuation systems for adjusting the location of the magnet 70. Referring to FIG. 3, an example fluid actuated magnet cylindrical post cathode 200 is disclosed. The fluid actuated magnet cylindrical post cathode 200 is a cylindrical tube. The side walls 210 of the tube are constructed of an evaporation source material. Each end of the tube is capped with a shield assembly 220. The shield assembly 220 covers and protects an electrical contact 222 that connects the cylindrical post cathode 200 to a power source 40 (illustrated in FIG. 1). The contact 222 is sealed to the side walls 210 via a standard o-ring 224. The contact 222 further includes an opening 226 that allows fluid from a cooling shaft 230 to enter the hollow center portion 240 of the cylindrical post cathode 200. Fluid flow into the center portion 240 of the cathode 200 is controlled via a top valve 250 and a bottom valve 252.

The magnet 260 is slidably mounted on the cooling shaft 230. The axial position of the magnet 260 is adjusted by altering the pressures of the cooling fluid 240 above and below the magnet 260. By increasing the pressure below the magnet 260, relative to the pressure above the magnet 260, the magnet 260 moves axially up along the cooling shaft 230. Likewise, decreasing the pressure below the magnet 260, relative to the pressure above the magnet 260, causes the magnet 260 to be moved axially down along the cooling shaft 230. In this way, a controller 22 (FIG. 1) can manipulate cooling fluid valves 250, 252 and thereby control the location of the magnet and the cathodic arc. Manipulation of the valves 250, 252 to affect the fluid pressure operates according to known principles.

Returning to the example of FIG. 1, any of the above described magnet actuation methods can be incorporated into the PVD system 10. FIG. 1 illustrates two parts 50 being coated. Alternately, the cylindrical post cathode 110 allows for coating the inside of a part 50 by sliding the part 50 onto the cathode 20 as a sleeve. This provides for a more consistent coverage of the interior surfaces of the part 50 than previous systems.

Although an example embodiment has been disclosed, a worker of ordinary skill in this art would recognize that certain modifications would come within the scope of the claims. For that reason, the following claims should be studied to determine their true scope and content.

What is claimed is:

1. A steered arc physical vapor deposition system comprising:
a vacuum chamber;
a cylindrical post cathode inside said vacuum chamber;
a magnet suspended within said cylindrical post cathode; and
a power source capable of providing a first charge to said cylindrical post cathode and a second charge to an anode, wherein said first charge and said second charge are opposite charges.

2. The steered arc physical vapor deposition system of claim 1, wherein said anode comprises an interior surface of said vacuum chamber.

3. The steered arc physical vapor deposition system of claim 1, wherein said anode comprises at least one anode structure positioned inside said vacuum chamber.

4. The steered arc physical vapor deposition system of claim 1, wherein said magnet is suspended within said cylindrical post cathode via a shaft, and said shaft and said cylindrical post cathode share an axis.

5. The steered arc physical vapor deposition system of claim 4, wherein said magnet is moveable along said shared axis.

6. The steered arc physical vapor deposition system of claim 5, wherein said magnet is suspended in a cooling fluid.

7. The steered arc physical vapor deposition system of claim 6, wherein a position of said magnet is dependent on a fluid pressure above said magnet and a fluid pressure below said magnet.

8. The steered arc physical vapor deposition system of claim 5, wherein said shaft is further connected to an actuator, thereby allowing said actuator to control an axial position of said magnet.

9. The steered arc physical vapor deposition system of claim 8, wherein said axial position of said magnet controls a position of a cathodic arc.

10. The steered arc physical vapor deposition system of claim 8, wherein said actuator is a cam actuator.

11. The steered arc physical vapor deposition system of claim 8, wherein said actuator is a linear actuator.

12. A post cathode for a steered arc physical vapor deposition system comprising:
a tube;
a magnet disposed within said tube, wherein said magnet is movable along an axis defined by said tube; and
wherein a side wall of said tube comprises an evaporation source material.

13. The post cathode of claim 12, wherein said tube is a cylindrical tube.

14. The cylindrical post cathode for a steered arc physical vapor deposition system of claim 13, wherein said magnet is moveable along said axis.

15. The cylindrical post cathode for a steered arc physical vapor deposition system of claim 13, wherein said magnet is mounted to a shaft.

16. The cylindrical post cathode for a steered arc physical vapor deposition system of claim 15, wherein said shaft is at least partially disposed within said cylindrical tube.

17. The cylindrical post cathode for a steered arc physical vapor deposition system of claim 15, wherein said shaft is an actuator shaft.

18. The cylindrical post cathode for a steered arc physical vapor deposition system of claim 15, wherein said shaft is fixed within said cylindrical tube and includes at least one passage for distributing cooling fluid to said cathode.

19. The cylindrical post cathode for a steered arc physical vapor deposition system of claim 18, wherein said magnet is slidably mounted to an outer surface of said shaft.
